(19) United States
(12) Patent Application Publication
(10) Pub. No.: US 2024/0166084 A1
(43) Pub. Date: May 23, 2024

(54) Server, System, and Method for Obtaining Battery Information

(71) Applicant: TOYOTA JIDOSHA KABUSHIKI KAISHA, Toyota-shi (JP)

(72) Inventors: Yasuhide KURIMOTO, Kasugai-shi (JP); Tomoyoshi UEKI, Toyota-shi (JP); Yuko TERASAWA, Meguro-ku (JP); Masahiro KAGAMI, Nagoya-shi (JP); Hiroshi YAMASAKI, Nagoya-shi (JP); Kenji ZAITSU, Nisshin-shi (JP); Yoshihiko ENDO, Tokyo-to (JP)

(21) Appl. No.: 18/492,834

(22) Filed: Oct. 24, 2023

(30) Foreign Application Priority Data
Nov. 18, 2022 (JP) 2022-185054

(51) Int. Cl. B60L 58/16; G01R 31/392; G06Q 30/0645

(52) U.S. Cl. CPC B60L 58/16; G01R 31/392; G06Q 30/0645; B60L 2250/00

(57) ABSTRACT

A server includes: a communication unit that communicates with a mobile terminal (terminal) of a user; and a processor (control unit) that controls the communication unit. When the communication unit has not received deterioration information (battery information) on a battery from the mobile terminal for greater than or equal to a cycle (predetermined period), the processor performs control for obtaining the deterioration information through the mobile terminal.

### CROSS REFERENCE TO RELATED APPLICATIONS

This nonprovisional application is based on Japanese Patent Application No. 2022-185054 filed on Nov. 18, 2022 with the Japan Patent Office, the entire contents of which are hereby incorporated by reference.

### BACKGROUND

### Field

The present disclosure relates to a server, a system, and a method for obtaining battery information.

### Description of the Background Art

Japanese Patent Laying-Open No. 2018-029430 discloses that a data center receives information about a secondary battery from an electric vehicle and calculates a degree of deterioration of the secondary battery.

### SUMMARY

Here, the information about the secondary battery cannot be transmitted from the electric vehicle to the data center when a communication device of the electric vehicle cannot communicate with the data center, or when the electric vehicle is not equipped with a communication device. In this case, it is difficult for a server to perform a predetermined process (e.g., calculation of a lease fee for the secondary battery) based on the information about the secondary battery. Thus, a server is desired that can obtain information about a secondary battery even when the information cannot be received from an electric vehicle.

The present disclosure was made to solve such a problem, and has an object to provide a server, a system, and a method for obtaining battery information, in which the server can obtain information about a secondary battery even when the information cannot be transmitted from an electric vehicle to the server.

A server according to a first aspect of the present disclosure is a server that receives battery information not from an electric vehicle but from a terminal of a user, the battery information being information about a secondary battery of the electric vehicle, the server including: a communication unit that communicates with the terminal; and a control unit that controls the communication unit. When the communication unit has not received the battery information from the terminal for greater than or equal to a predetermined period, the control unit performs control for obtaining the battery information through the terminal.

In the server according to the first aspect of the present disclosure, as described above, when the communication unit has not received the battery information from the terminal for greater than or equal to the predetermined period, the control for obtaining the battery information through the terminal is performed. Accordingly, even when the electric vehicle cannot transmit the information about the secondary battery to the server, the server can obtain the information through the terminal of the user.

In the server according to the first aspect, preferably, the secondary battery is leased to the user, and the control unit calculates a lease fee for the secondary battery using the battery information for each predetermined period. With such a configuration, when the communication unit has not received the battery information from the terminal for greater than or equal to the predetermined period, which is a cycle of calculation of the lease fee, the server can perform the control for obtaining the battery information through the terminal. As a result, the battery information can be readily updated when the lease fee is calculated.

In the server according to the first aspect, preferably, when the communication unit has not received the battery information from the terminal for greater than or equal to the predetermined period, the control unit causes the terminal to perform control of transmitting the battery information to the communication unit. With such a configuration, the server can more reliably obtain the information about the secondary battery through the terminal of the user.

In this case, preferably, when the communication unit has not received the battery information from the terminal for greater than or equal to the predetermined period, the control unit performs control of transmitting a signal to the terminal through the communication unit, the signal controlling the terminal to obtain the battery information from the electric vehicle and to transmit the obtained battery information to the communication unit. With such a configuration, the battery information transmitted from the electric vehicle to the terminal of the user can be readily transmitted from the terminal to the server.

In the server according to the first aspect, preferably, when the communication unit has not received the battery information from the terminal for greater than or equal to the predetermined period, the control unit provides a notification prompting the user to transmit the battery information from the terminal to the communication unit. With such a configuration, the information about the secondary battery can be transmitted from the user to the server. As a result, the server can readily obtain the information about the secondary battery.

In the server according to the first aspect, preferably, the battery information includes information about a degree of deterioration of the secondary battery. With such a configuration, even when the electric vehicle cannot transmit the information about the degree of deterioration of the secondary battery to the server, the server can obtain the information about the degree of deterioration of the secondary battery through the terminal of the user.

A system according to a second aspect of the present disclosure includes: a terminal of a user of an electric vehicle including a secondary battery; and a server that communicates with the terminal. The server receives battery information not from the electric vehicle but from the terminal, the battery information being information about the secondary battery, and when the server has not received the battery information from the terminal for greater than or equal to a predetermined period, performs control for obtaining the battery information through the terminal.

In the system according to the second aspect of the present disclosure, as described above, when a communication unit has not received the battery information from the terminal for greater than or equal to the predetermined period, the control for obtaining the battery information through the terminal is performed. Accordingly, a system can be provided in which, even when an electric vehicle cannot transmit information about a secondary battery to a server, the server can obtain the information through a terminal of a user.

A method for obtaining battery information according to a third aspect of the present disclosure is a method for obtaining battery information by a server that receives the battery information not from an electric vehicle but from a terminal of a user of the electric vehicle, the battery information being information about a secondary battery of the electric vehicle, the method including: communicating with the terminal; and when the server has not received the battery information from the terminal for greater than or equal to a predetermined period, performing control for obtaining the battery information through the terminal.

In the method for obtaining battery information according to the third aspect of the present disclosure, as described above, when a communication unit has not received the battery information from the terminal for greater than or equal to the predetermined period, the control for obtaining the battery information through the terminal is performed. Accordingly, a method for obtaining battery information can be provided in which, even when an electric vehicle cannot transmit information about a secondary battery to a server, the server can obtain the information through a terminal of a user.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 shows a configuration of a system according to a first embodiment.

FIG. 2 shows a cycle of calculation of a lease fee for a battery.

FIG. 3 shows sequence control of the system according to the first embodiment.

FIG. 4 shows a configuration of a system according to a second embodiment.

FIG. 5 shows sequence control of the system according to the second embodiment.

### DESCRIPTION OF THE PREFERRED EMBODIMENTS

### First Embodiment

A first embodiment of the present disclosure will be described in detail below with reference to the drawings. In the drawings, the same or corresponding parts are denoted by the same reference characters, and a description thereof will not be repeated.

FIG. 1 shows a configuration of a system 1 according to the first embodiment. System 1 includes a server 100, an electric vehicle 10, and a mobile terminal 14 (e.g., a smartphone). Mobile terminal 14 is a terminal of a user of electric vehicle 10. System 1 may not include electric vehicle 10. Mobile terminal 14 is an example of “terminal” of the present disclosure.

Electric vehicle 10 includes, for example, a plug-in hybrid electric vehicle (PHEV), a battery electric vehicle (BEV), and a fuel cell electric vehicle (FCEV).

Electric vehicle 10 includes a navigation system 11, a communication device 12, and a battery 13. Battery 13 supplies electric power to electrical equipment such as navigation system 11 and communication device 12. Battery 13 is leased to the user of electric vehicle 10 from a management company of battery 13. Battery 13 is an example of “secondary battery” of the present disclosure.

Communication device 12 may include a data communication module (DCM), or a 5G (fifth-generation mobile communications system)-enabled communication I/F.

Server 100 is configured to manage information on registered electric vehicles 10 (hereinafter also referred to as “vehicle information”) and information on registered users (hereinafter also referred to as “user information”). The user information and the vehicle information are stored in a memory 102 described later herein as being distinguished based on identification information (ID).

A user ID is identification information for identification of a user, and also serves as information (a terminal ID) that identifies mobile terminal 14 carried by the user. Server 100 is configured to store information received from mobile terminal 14 as being distinguished based on the user ID. The user information includes a communication address of mobile terminal 14, and a vehicle ID of electric vehicle 10.

The vehicle ID is identification information for identification of electric vehicle 10. The vehicle ID may be a license plate or a vehicle identification number (VIN). The vehicle information includes an operation schedule of electric vehicle 10.

Server 100 includes a processor 101, memory 102, a communication unit 103, and a timer 104. Processor 101 controls communication unit 103. Processor 101 is an example of “control unit” of the present disclosure.

Memory 102 stores, in addition to programs for execution by processor 101, information (e.g., maps, mathematical formulas, and various parameters) for use in the programs.

Memory 102 also stores information about a degree of deterioration of battery 13 of electric vehicle 10 (hereinafter referred to as deterioration information). The deterioration information includes information on a capacity retention (unit:%) of battery 13. The deterioration information stored in memory 102 is updated each time new deterioration information is received by communication unit 103. The deterioration information on battery 13 is an example of “battery information” of the present disclosure.

The capacity retention of battery 13 means the ratio (percentage) of a full charge capacity C of battery 13 at a current time to a full charge capacity C0 of battery 13 in an initial state (e.g., a state when battery 13 was manufactured) (Q=C/C0). However, an EV travel distance (unit:km) of electric vehicle 10 may be used instead of, or in addition to, the capacity retention of battery 13, as the deterioration information on battery 13. Alternatively, the full charge capacity (unit:Ah or Wh) itself of battery 13 may be used as the deterioration information on battery 13.

Furthermore, any two or all three of the capacity retention, the EV travel distance and the full charge capacity may be used as the deterioration information on battery 13. Alternatively, the degree of deterioration (100−capacity retention [%]) of battery 13 may be used as the deterioration information on battery 13.

Communication unit 103 of server 100 communicates with mobile terminal 14. Communication unit 103 receives the deterioration information on battery 13 not from electric vehicle 10 (communication device 12) but from mobile terminal 14.

Mobile terminal 14 can carry out short-range wireless communication with communication device 12 of electric vehicle 10. Mobile terminal 14 receives the deterioration information on battery 13 from communication device 12 during the short-range wireless communication with communication device 12. Specifically, mobile terminal 14 receives the deterioration information from communication device 12 for each predetermined cycle (e.g., every one hour) during the short-range wireless communication with communication device 12. The deterioration information may be transmitted from communication device 12 to mobile terminal 14 immediately after the short-range wireless communication has been established between mobile terminal 14 and communication device 12.

Alternatively, information for calculation of the capacity retention of battery 13 may be transmitted, instead of the information on the capacity retention of battery 13, from mobile terminal 14 to communication unit 103 of server 100.

Timer 104 measures an elapsed time from the point when server 100 obtained the deterioration information on battery 13. Timer 104 counts up (adds) the elapsed time for each predetermined time (e.g., every one second).

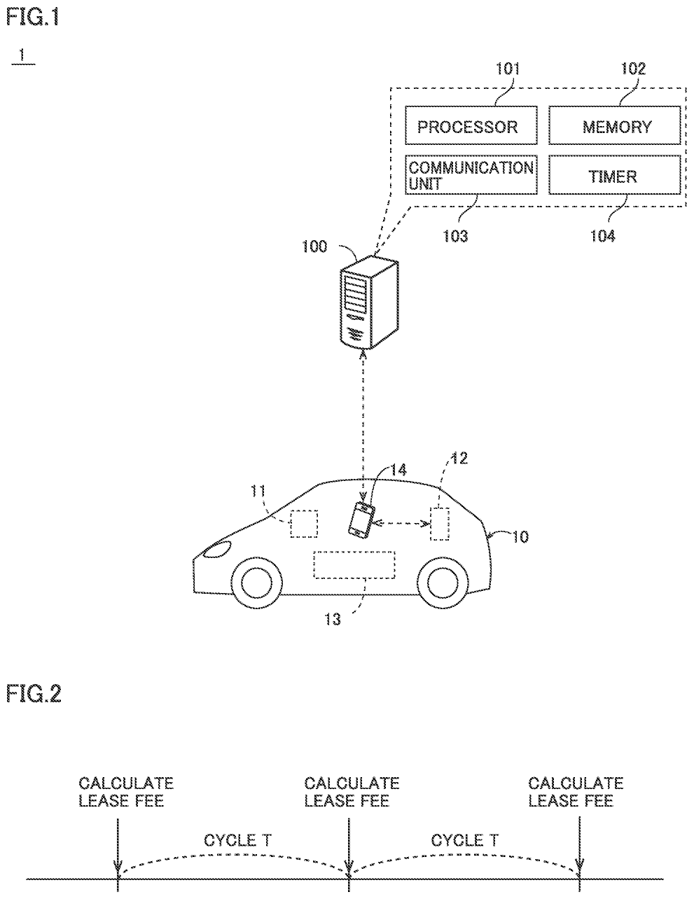

As shown in FIG. 2, processor 101 calculates a lease fee for battery 13 using the deterioration information on battery 13 for each cycle T (e.g., every 24 hours). For example, processor 101 may calculate the lease fee for battery 13 by reference to a table that indicates a relationship between the capacity retention of battery 13 and the lease fee for battery 13. The table may be stored in memory 102. Cycle T is an example of “predetermined period” of the present disclosure.

Here, the deterioration information on battery 13 cannot be transmitted from electric vehicle 10 to server 100, such as when communication device 12 of electric vehicle 10 cannot communicate with server 100. In this case, it is difficult for server 100 to perform a predetermined process (e.g., calculation of the lease fee for battery 13) based on the deterioration information on battery 13. Thus, server 100 is desired that can obtain the deterioration information on battery 13 even when the deterioration information cannot be received from electric vehicle 10.

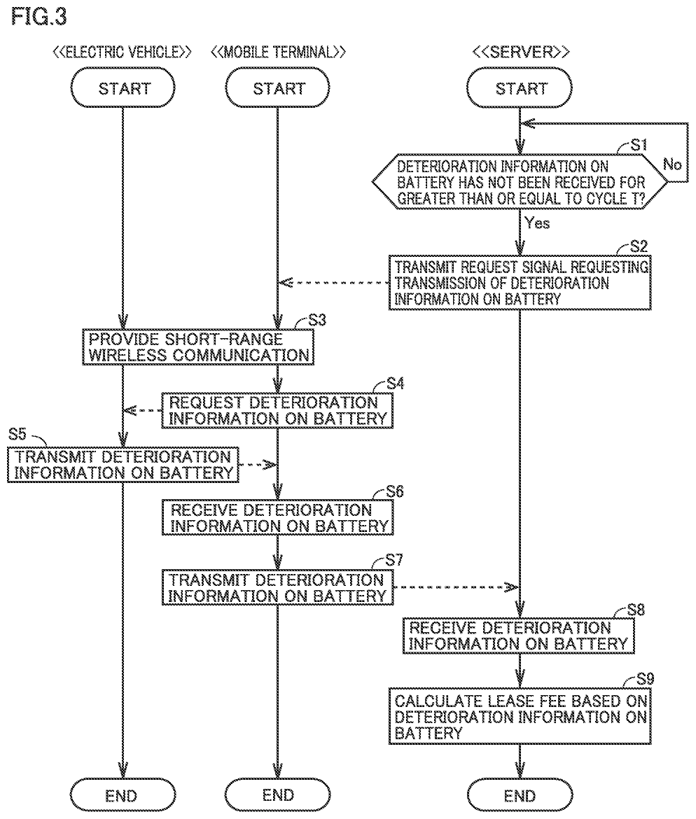

In the first embodiment, therefore, when communication unit 103 has not received the deterioration information from mobile terminal 14 for greater than or equal to cycle T, processor 101 performs control for obtaining the deterioration information through mobile terminal 14. Specifically, when the elapsed time measured by timer 104 becomes greater than or equal to cycle T, processor 101 performs control for obtaining the deterioration information through mobile terminal 14. The details are described with reference to a sequence diagram of FIG. 3.

### (Method for Obtaining Battery Information)

A method for obtaining the deterioration information on battery 13 by server 100 is described with reference to the sequence diagram of FIG. 3.

In step S1, server 100 (processor 101) determines whether or not communication unit 103 has not received the deterioration information on battery 13 for greater than or equal to cycle T. Specifically, processor 101 determines whether or not the time measured by timer 104 (the elapsed time since the last time communication unit 103 received the deterioration information) is greater than or equal to cycle T. When the deterioration information has not been received for greater than or equal to cycle T (Yes in S1), the process proceeds to step S2. When the elapsed time since the last time communication unit 103 received the deterioration information is less than cycle T (No in S1), the process of step S1 is repeated.

In step S2, processor 101 transmits a request signal requesting transmission of the deterioration information on battery 13 to mobile terminal 14 through communication unit 103.

In step S3, mobile terminal 14 performs, in response to the request signal in step S2, a process of providing short-range wireless communication with electric vehicle 10 (communication device 12). As a result, short-range wireless communication is provided (established) between electric vehicle 10 (communication device 12) and mobile terminal 14.

In step S4, mobile terminal 14 transmits the request signal requesting the deterioration information on battery 13 to communication device 12 of electric vehicle 10.

In step S5, electric vehicle 10 transmits, in response to the request signal in step S4, the deterioration information on battery 13 to mobile terminal 14 through communication device 12.

In step S6, mobile terminal 14 obtains the deterioration information on battery 13 transmitted from electric vehicle 10 in step S5.

In step S7, mobile terminal 14 transmits the deterioration information on battery 13 received in step S6 to server 100 (communication unit 103). The process performed in mobile terminal 14 from steps S3 to S7 is an example of “control of transmitting battery information to a communication unit” of the present disclosure.

In step S8, communication unit 103 of server 100 obtains the deterioration information on battery 13 transmitted from mobile terminal 14 in step S7.

In step S9, processor 101 calculates a lease fee for battery 13 based on the deterioration information on battery 13 received in step S8. Specifically, processor 101 calculates the lease fee for battery 13 by reference to the table that is stored in memory 102 and that indicates the relationship between the capacity retention of battery 13 and the lease fee for battery 13. Processor 101 may calculate the lease fee for battery 13 using a computational equation that calculates the lease fee for battery 13 based on the capacity retention of battery 13.

As described above, in the first embodiment, when communication unit 103 has not received the deterioration information on battery 13 from mobile terminal 14 for greater than or equal to cycle T, processor 101 performs the control for obtaining the deterioration information through mobile terminal 14. Accordingly, processor 101 can prevent the period during which the deterioration information is not obtained from becoming greater than or equal to cycle T.

### Second Embodiment

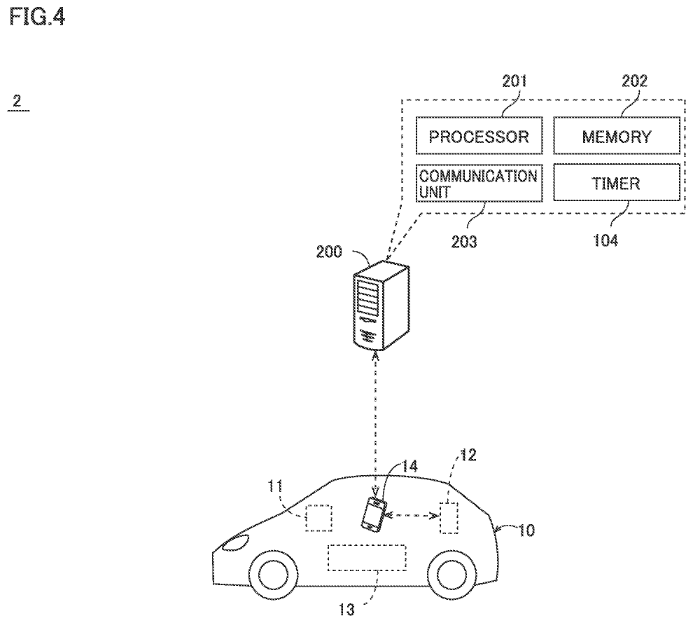

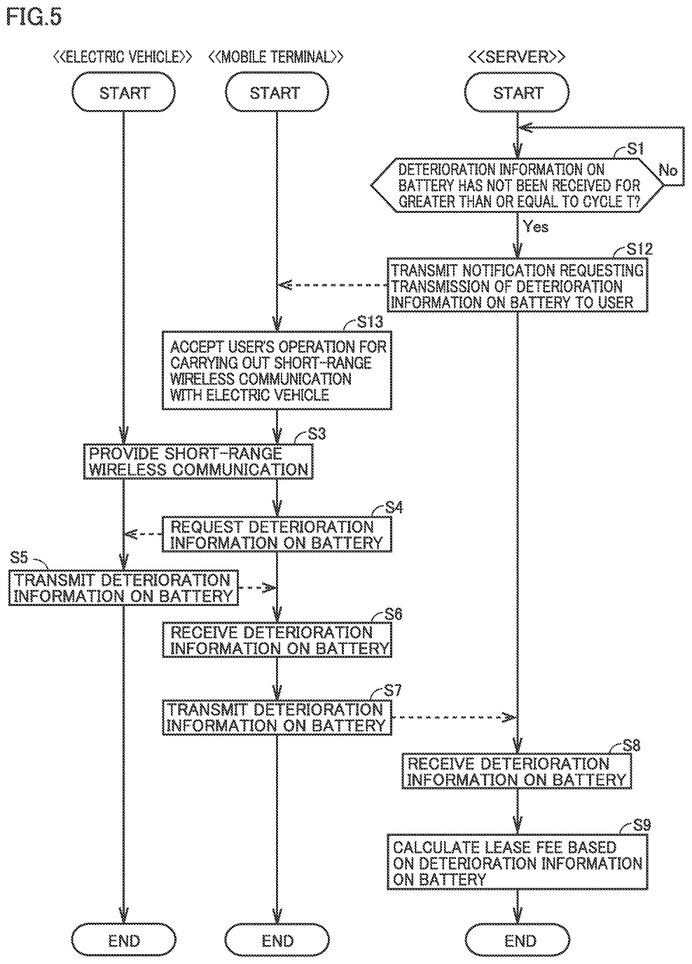

Referring now to FIGS. 4 and 5, a server 200 and a system 2 in a second embodiment are described. Unlike the first embodiment where the request signal requesting transmission of the deterioration information on battery 13 is transmitted to mobile terminal 14, a notification prompting transmission of the deterioration information is transmitted to the user in the second embodiment. The same components as those of the first embodiment are denoted by the same reference characters as those of the first embodiment, and a description thereof will not be repeated.

FIG. 4 shows a configuration of system 2 according to the second embodiment. System 2 includes server 200, electric vehicle 10, and mobile terminal 14. System 2 may not include electric vehicle 10.

Server 200 includes a processor 201, a memory 202, a communication unit 203, and timer 104. Processor 201 controls communication unit 203. Processor 201 is an example of “control unit” of the present disclosure.

Memory 202 stores, in addition to programs for execution by processor 201, information (e.g., maps, mathematical formulas, and various parameters) for use in the programs. Memory 202 also stores the deterioration information on battery 13 of electric vehicle 10.

### (Method for Obtaining Battery Information)

A method for obtaining the deterioration information on battery 13 by server 200 is described with reference to a sequence diagram of FIG. 5. The same process steps as those of the sequence diagram of the first embodiment are denoted by the same reference characters as those of the first embodiment, and a description thereof will not be repeated.

When the determination is Yes in step S1, the process proceeds to step S12. In step S12, processor 201 provides a notification prompting the user to transmit the deterioration information on battery 13 from mobile terminal 14 to communication unit 203. Specifically, processor 201 transmits a message prompting provision of short-range wireless communication with electric vehicle 10 to mobile terminal 14 through communication unit 203.

In step S13, mobile terminal 14 accepts the user's operation for providing short-range wireless communication with electric vehicle 10. Accordingly, in step S3, short-range wireless communication is provided between electric vehicle 10 and mobile terminal 14.

The configuration in the second embodiment is otherwise the same as the first embodiment, and thus, a description thereof will not be repeated.

Although the first and second embodiments illustrate an example where the control for obtaining the deterioration information through mobile terminal 14 is performed when communication unit 103 (203) has not obtained the deterioration information for greater than or equal to cycle T of calculation of the lease fee for battery 13, the present disclosure is not limited as such. The control for obtaining the deterioration information through mobile terminal 14 may be performed when communication unit 103 (203) has not obtained the deterioration information for greater than or equal to a period different from cycle T (e.g., ½ of cycle T).

Although the first and second embodiments illustrate an example where it is determined whether or not the deterioration information on battery 13 has not been received by server 100 (200) for greater than or equal to cycle T (predetermined cycle), the present disclosure is not limited as such. It may be determined whether or not information other than the deterioration information on battery 13 (e.g., information on a state of charge (SOC) of battery 13) has not been received by server 100 (200) for greater than or equal to cycle T.

Although the first and second embodiments illustrate an example where processor 101 (201) calculates the lease fee for battery 13 based on the deterioration information (battery information) of battery 13, the present disclosure is not limited as such. For example, processor 101 (201) may set the next maintenance (or replacement) timing for battery 13 based on the deterioration information on battery 13.

Although the first and second embodiments illustrate an example where the deterioration information on battery 13 is transmitted and received by mobile terminal 14 of the user, the present disclosure is not limited as such. For example, the deterioration information on battery 13 may be transmitted and received by a PC of the user. The PC may include both a portable PC and a stationary (non-portable) PC.

Although the second embodiment illustrates an example where the notification prompting establishment of short-range wireless communication between mobile terminal 14 and electric vehicle 10 is transmitted from server 200 to mobile terminal 14 of the user, the present disclosure is not limited as such. For example, a notification prompting a wired cable connection of mobile terminal 14 to electric vehicle 10 may be transmitted from server 200 to mobile terminal 14 of the user.

The embodiments described above and the configuration (process) of each variation described above may be combined with each other.

Although embodiments of the present disclosure have been described, it should be understood that the embodiments disclosed herein are illustrative and non-restrictive in every respect. The scope of the present disclosure is defined by the terms of the claims and is intended to include any modifications within the scope and meaning equivalent to the terms of the claims.

What is claimed is:

1. A server that receives battery information not from an electric vehicle but from a terminal of a user of the electric vehicle, the battery information being information about a secondary battery of the electric vehicle, the server comprising:
a communication unit that communicates with the terminal; and
a control unit that controls the communication unit, wherein
when the communication unit has not received the battery information from the terminal for greater than or equal to a predetermined period, the control unit performs control for obtaining the battery information through the terminal.

2. The server according to claim 1, wherein
the secondary battery is leased to the user, and
the control unit calculates a lease fee for the secondary battery using the battery information for each predetermined period.

3. The server according to claim 1, wherein
when the communication unit has not received the battery information from the terminal for greater than or equal to the predetermined period, the control unit causes the terminal to perform control of transmitting the battery information to the communication unit.

4. The server according to claim 3, wherein
when the communication unit has not received the battery information from the terminal for greater than or equal to the predetermined period, the control unit performs control of transmitting a signal to the terminal through the communication unit, the signal controlling the terminal to obtain the battery information from the electric vehicle and to transmit the obtained battery information to the communication unit.

5. The server according to claim 1, wherein
when the communication unit has not received the battery information from the terminal for greater than or equal to the predetermined period, the control unit provides a notification prompting the user to transmit the battery information from the terminal to the communication unit.

6. The server according to claim 1, wherein
the battery information includes information about a degree of deterioration of the secondary battery.

7. A system comprising:
a terminal of a user of an electric vehicle including a secondary battery; and
a server that communicates with the terminal, wherein
the server
receives battery information not from the electric vehicle but from the terminal, the battery information being information about the secondary battery, and
when the server has not received the battery information from the terminal for greater than or equal to a predetermined period, performs control for obtaining the battery information through the terminal.

8. A method for obtaining battery information by a server that receives the battery information not from an electric vehicle but from a terminal of a user of the electric vehicle, the battery information being information about a secondary battery of the electric vehicle, the method comprising:
communicating with the terminal; and
when the server has not received the battery information from the terminal for greater than or equal to a predetermined period, performing control for obtaining the battery information through the terminal.
